(19) United States
(12) Patent Application Publication
(10) Pub. No.: US 2017/0155046 A1
(43) Pub. Date: Jun. 1, 2017

(54) INK COMPONENT MANAGEMENT METHOD, INKJET SYSTEM USING SAME, AND MANUFACTURING METHOD FOR MANUFACTURING ORGANIC EL DISPLAY DEVICE USING INKJET SYSTEM

(71) Applicant: JOLED INC., Tokyo (JP)

(72) Inventor: Yuko KAWANAMI, Tokyo (JP)

(73) Assignee: JOLED INC., Tokyo (JP)

(21) Appl. No.: 15/322,827

(22) PCT Filed: Jun. 25, 2015
(86) PCT No.: PCT/JP2015/003193

§ 371 Date: Dec. 29, 2016

(30) Foreign Application Priority Data
Jun. 30, 2014 (JP) 2014-134850

(51) Int. Cl. H01L 51/00; H01L 51/56; B05D 1/26

(52) U.S. Cl. CPC H01L 51/0005; B05D 1/26; H01L 51/56

(57) ABSTRACT

A method of managing components of ink that can suppress changes in composition of a mixed solvent in ink that is stored in an inkjet device. A method for managing components of ink stored in an inkjet device under a negative pressure environment, the ink including a functional material, a first solvent, and a second solvent that has a higher boiling point and viscosity than the first solvent, the inkjet device discharging the ink via nozzles, the method including preparing a mixed solvent including a solvent identical to the first solvent and a solvent identical to the second solvent at a composition ratio that depends on a volatilization amount of the first solvent per unit time and a volatilization amount of the second solvent per unit time; and adding the mixed solvent to the ink stored in the inkjet device.

### TECHNICAL FIELD

The present invention relates to methods of managing components of ink stored in inkjet devices, inkjet systems using same, and methods of manufacturing organic electroluminescence (EL) display devices using such inkjet systems.

### BACKGROUND ART

In recent years, research and development is progressing for organic EL elements that are light-emitting elements that use electroluminescence of organic material, and have a light-emitting layer disposed between an anode and a cathode. Typically, an organic EL element is bounded by banks made from insulating material, and an anode, a light-emitting layer, and a cathode are formed between these banks. Further, between the anode and the cathode, aside from the light-emitting layer, a charge injection layer, a charge transport layer, etc., may be provided as required. Light-emitting layers, charge injection layers, charge transport layers, etc., are collectively referred to as functional layers.

Organic EL elements are arranged in a matrix, forming an organic EL display device. When manufacturing an organic EL display device, there is a process of forming a functional layer on a substrate. In recent years, as substrates become bigger, inkjet systems that incorporate an inkjet device for forming a functional layer are becoming widely used. Such inkjet devices apply ink in which a functional material is dissolved in a solvent between pairs of banks formed on a substrate. Further, in order to obtain high-definition images in organic EL display devices, there is demand to form micro-size organic EL elements for which a length of an edge thereof is equal to or less than 500 μm. In such micro-size organic EL elements, for each organic EL element, a film thickness of a functional layer is necessarily only tens to hundreds of nanometers thick. For this reason, stricter control of film thickness and planarity of functional layers is sought.

Thus, ink is prepared for which organic material is dissolved in a solvent mix of an appropriate ratio of a first solvent that has a low viscosity and a low boiling point and a second solvent that has a high viscosity and a high boiling point. A method has been proposed that forms a uniform and planar functional layer across an organic EL display device by applying such ink onto a substrate (Patent Literature 1). By using an ink that uses a mix of a first solvent and a second solvent, a low viscosity of ink is maintained at the time of ink discharge. Further, after application between banks, the first solvent that has a low boiling point quickly evaporates, causing a sharp change to a high viscosity, suppressing flow of ink. According to Patent Literature 1, planarity of a functional layer can be increased by appropriate adjustment of a composition ratio of the first solvent and the second solvent.

### CITATION LIST

### Patent Literature

[Patent Literature 1] JP 2013-214397

[Patent Literature 2] JP 2007-69140

### SUMMARY OF INVENTION

### Technical Problem

In an inkjet system, ink is stored in an inkjet device and the ink is discharged onto a substrate from nozzles provided on an inkjet head in the inkjet device. Normally, ink in an inkjet device is stored under a negative pressure environment so that the ink does not leak from a nozzle under its own weight. However, when ink in an inkjet device is stored under a negative pressure environment, solvent may volatilize from the ink. When this occurs, ink concentration increases as time passes, and therefore viscosity of the ink increases. When viscosity of the ink increases, an amount of ink discharged from a nozzle can change. Thus, film thickness of a functional layer becomes different for a product manufactured using an initial ink mix and a product manufactured using ink stored for a long period of time and, as a result, there is a risk of electrical properties and optical properties of organic EL display devices changing greatly, light emission efficiency decreasing, and color quality decreasing.

To counter this, a mixed solvent that is a mix of a solvent identical to the first solvent and a solvent identical to the second solvent can be prepared, and regularly or irregularly added to the ink in the inkjet device. A composition ratio of the mixed solvent could simply be matched to a composition ratio of the first solvent and the second solvent in the initial ink mix.

However, when such a mixed solvent is added to the ink, ink concentration decreases, and therefore although an increase in viscosity of the ink is suppressed, the composition ratio of the first solvent and the second solvent in the ink becomes different to the composition ratio in the initial ink mix.

Thus, the present invention aims to provide a method of managing components of ink that can suppress changes in composition of a mixed solvent in ink that is stored in an inkjet device.

### Solution to Problem

In order to solve the above technical problem, a method pertaining to one aspect of the present invention is a method for managing components of ink stored in an inkjet device under a negative pressure environment, the ink including a functional material, a first solvent, and a second solvent that has a higher boiling point and viscosity than the first solvent, the inkjet device discharging the ink via nozzles, the method comprising: preparing a mixed solvent including a solvent identical to the first solvent and a solvent identical to the second solvent at a composition ratio that depends on a volatilization amount of the first solvent per unit time and a volatilization amount of the second solvent per unit time; and adding the mixed solvent to the ink stored in the inkjet device.

### Advantageous Effects of Invention

Boiling points of the first solvent and the second solvent are different, and therefore volatilization amounts per unit time of each solvent are different. Thus, if a mixed solvent were added in which the composition ratio were matched to the composition ratio of each solvent in the initial ink mix, the composition ratio of the mixed solvent in the ink stored in the inkjet device would change from the composition ratio of the mixed solvent in the initial ink mix. Here, according to the method pertaining to one aspect of the present invention, a mixed solvent is prepared in a composition ratio according to volatilization amounts per unit time of each solvent, and then added.

Thus, it is possible to suppress changes in composition of a mixed solvent in ink that is stored in an inkjet device.

### BRIEF DESCRIPTION OF DRAWINGS

FIG. 1 is a schematic diagram showing an inkjet system 1 pertaining to an embodiment.

FIG. 2 is a perspective view showing an inkjet device 100 pertaining to an embodiment.

FIG. 3 is a schematic diagram for describing a relationship between temperature, vapor pressure, and boiling point.

FIG. 4 is a schematic diagram for describing change over time of a ratio in ink of a first solvent to a second solvent.

FIG. 5 is a graph showing a relationship between viscosity of ink and days elapsed after ink introduction.

FIG. 6 is a graph showing a relationship between viscosity of ink when a mixed solvent is added and an added amount of the mixed solvent.

FIG. 7 is an overview flowchart of a control unit 13.

FIG. 8 is a flowchart of addition processing in FIG. 7.

FIG. 9 is a flowchart of replenishment processing in FIG. 7.

FIG. 10A shows results of measuring a surface state of a functional layer when the functional layer was formed by ink using a mixed solvent for which 1-methylnaphthalene and heptylbenzene were mixed in a mass ratio of 2:8; and FIG. 10B shows results of measuring a surface state of a functional layer when the functional layer was formed by ink using a mixed solvent for which 1-methylnaphthalene and heptylbenzene were mixed in a mass ratio of 3:7.

FIG. 11 is a schematic diagram showing a schematic configuration of an organic EL display device 10000 pertaining to an embodiment.

FIG. 12 is a plan view showing an arrangement of organic EL elements 1001R, 1001G, 1001B in an organic EL display panel 3000.

FIG. 13 shows a cross section of A-A in FIG. 12.

FIG. 14 shows a process of manufacturing the organic EL display panel 3000.

### DESCRIPTION OF EMBODIMENT

An embodiment of the present invention is described in detail with reference to the drawings.

### Aspects of the Invention

A method pertaining to one aspect of the present invention is a method for managing components of ink stored in an inkjet device under a negative pressure environment, the ink including a functional material, a first solvent, and a second solvent that has a higher boiling point and viscosity than the first solvent, the inkjet device discharging the ink via nozzles, the method comprising: preparing a mixed solvent including a solvent identical to the first solvent and a solvent identical to the second solvent at a composition ratio that depends on a volatilization amount of the first solvent per unit time and a volatilization amount of the second solvent per unit time; and adding the mixed solvent to the ink stored in the inkjet device.

According to another example of the present invention, R=(Aa/Bb)×(M_{b}/Mₐ)×(Pₐ/P_{b}), where R is a ratio of a volatilization amount of the solvent identical to the first solvent per unit time to a volatilization amount of the solvent identical to the second solvent per unit time, a is a mass at room temperature per unit volume of the solvent identical to the first solvent, Mₐ is a molecular weight of the solvent identical to the first solvent, Pₐ is a vapor pressure at room temperature of the solvent identical to the first solvent, b is a mass at room temperature per unit volume of the solvent identical to the second solvent, M_{b} is a molecular weight of the solvent identical to the second solvent, P_{b} is a vapor pressure at room temperature of the solvent identical to the second solvent, and A:B is a ratio of volume of the first solvent to volume of the second solvent.

Further, according to another example of the present invention, the mixed solvent is added to the ink at a quantity Q1 per unit time, and Q1=C1/C2, where C1 is an average rate of change of viscosity of the ink when stored in the inkjet device and the mixed solvent is not added and C2 is an average rate of change of viscosity of the ink per added amount of the mixed solvent when the mixed solvent is added to the ink.

Further, according to another example of the present invention, the inkjet device comprises an inkjet head that includes the nozzles and an IN tank that is connected to the inkjet head and stores the ink for supplying the inkjet head, and the adding the mixed solvent to the ink stored in the inkjet device is performed by adding the mixed solvent to the IN tank.

Further, according to another example of the present invention, the mixed solvent is stored under a higher pressure environment than the ink stored in the ink jet device.

Further, according to another example of the present invention, the functional material is a macromolecular organic material.

An inkjet system pertaining to one aspect of the present invention is an inkjet system comprising: an inkjet device that stores ink under a negative pressure environment, the ink including a functional material, a first solvent, and a second solvent that has a higher boiling point and viscosity than the first solvent, the inkjet device discharging the ink via nozzles; a mixed solvent tank that is connected to the inkjet device via a pipe, the mixed solvent tank storing a mixed solvent including a solvent identical to the first solvent and a solvent identical to the second solvent at a composition ratio that depends on a volatilization amount of the first solvent per unit time and a volatilization amount of the second solvent per unit time; a valve provided to the pipe; and a control unit that controls the valve to allow the mixed solvent stored in the mixed solvent tank to be added to the inkjet device.

Further, according to another example of the present invention, R=(Aa/Bb)×(M_{b}/Mₐ)×(Pₐ/P_{b}), where R is a ratio of a volatilization amount of the solvent identical to the first solvent per unit time to a volatilization amount of the solvent identical to the second solvent per unit time, a is a mass at room temperature per unit volume of the solvent identical to the first solvent, Mₐ is a molecular weight of the solvent identical to the first solvent, Pₐ is a vapor pressure at room temperature of the solvent identical to the first solvent, b is a mass at room temperature per unit volume of the solvent identical to the second solvent, M_{b} is a molecular weight of the solvent identical to the second solvent, P_{b} is a vapor pressure at room temperature of the solvent identical to the second solvent, and A:B is a ratio of volume of the first solvent to volume of the second solvent.

Further, according to another example of the present invention, the mixed solvent is added to the ink at a quantity Q1 per unit time, and Q1=C1/C2, where C1 is an average rate of change of viscosity of the ink when stored in the inkjet device and the mixed solvent is not added and C2 is an average rate of change of viscosity of the ink per added amount of the mixed solvent when the mixed solvent is added to the ink.

Further, according to another example of the present invention, the inkjet device comprises an inkjet head that includes the nozzles and an IN tank that is connected to the inkjet head and stores the ink for supplying the inkjet head, and the mixed solvent is added to the ink stored in the inkjet device is by adding the mixed solvent to the IN tank.

Further, according to another example of the present invention, the mixed solvent is stored under a higher pressure environment than the ink stored in the ink jet device.

Further, according to another example of the present invention, the functional material is a macromolecular organic material.

A method for manufacturing an organic EL display device pertaining to one aspect of the present invention is a method comprising: preparing an underlying substrate; forming a first electrode on the underlying substrate; forming a functional layer above the first electrode, from the functional material, by using the inkjet system according to the above aspect; and forming a second electrode above the functional layer.

### Embodiment

(1) Inkjet System

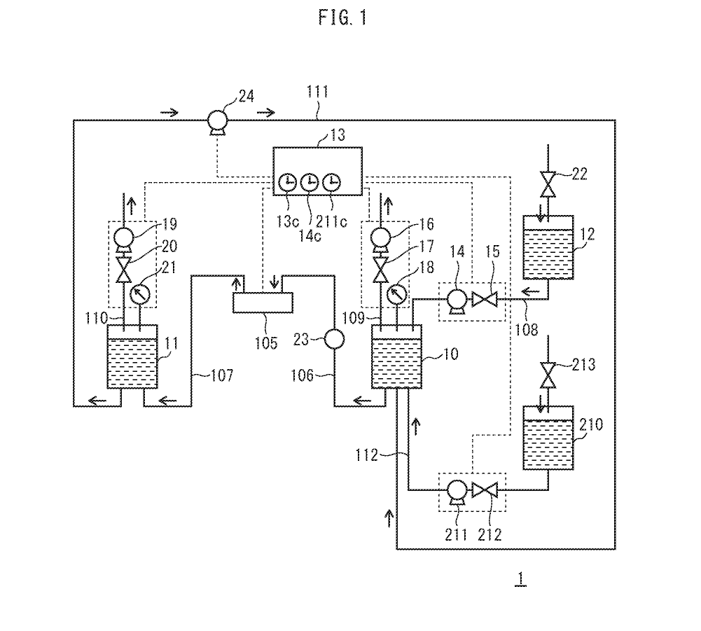

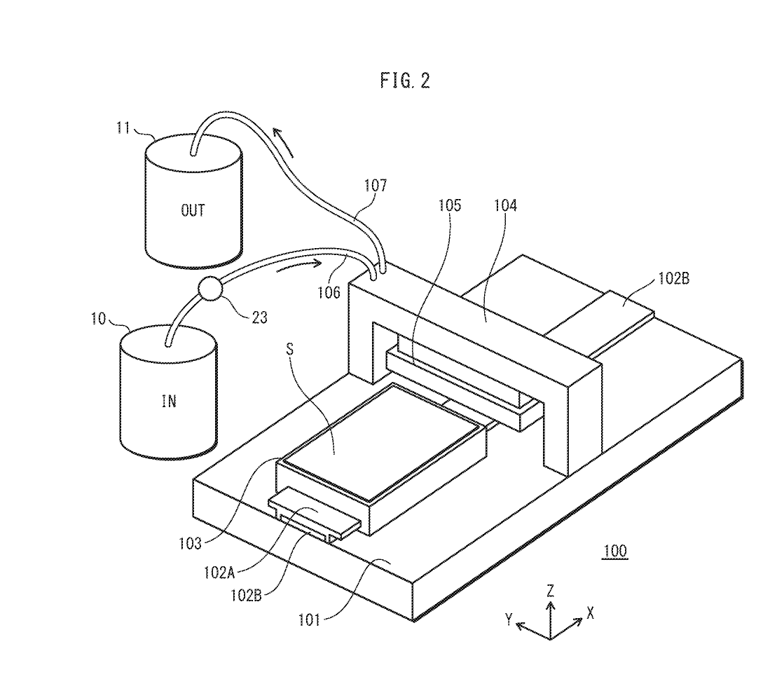

FIG. 1 is a schematic diagram showing an inkjet system 1. The inkjet system 1 includes an inkjet head 105, an IN tube 106 and an IN tank 10 that supply ink to the inkjet head 105, and an OUT tube 107 and an OUT tank 11 that recover ink from the inkjet head 105. The IN tube 106 includes a flowmeter 23 that measures flow of ink supplied to the inkjet head 105. The inkjet head 105 is supplied ink from the IN tank 10 via the IN tube 106. Ink is recovered from the inkjet head 105 to the OUT tank 11 via the OUT tube 107. The inkjet device includes the IN tank 10, the IN tube 106, the flowmeter 23, the OUT tank 11, the OUT tube 107, and the inkjet head 105 (see FIG. 2).

According to the embodiment, when forming a functional layer of an organic EL display panel by a wet application method, the inkjet system 1 is used in a process of wet application of a functional material of the functional layer onto a substrate. Ink includes the functional material as a solute, a first solvent, and a second solvent that has a higher boiling point and viscosity than the first solvent.

The inkjet system 1 further includes a mixed solvent tank 12 and a replenishment tank 210. The mixed solvent tank 12 is connected to the IN tank 10 via a tube 108 and stores a mixed solvent that is a mix of a solvent that is identical to the first solvent and a solvent that is identical to the second solvent. The replenishment tank 210 is connected to the IN tank 10 via a tube 112 and stores ink that includes a material that is identical to the functional material, a solvent that is identical to the first solvent, and a solvent that is identical to the second solvent. Here, “identical to” means that the substance or composition is the same. For example, when the first solvent is 1-methylnaphthalene, the solvent that is identical to the first solvent is also 1-methylnaphthalene. Composition ratio of the mixed solvent stored in the mixed solvent tank 12 is described in detail later. The tube 108 that connects the mixed solvent tank 12 and the IN tank 10 is provided with a valve 15 and a pump 14 for adjusting flow of the mixed solvent. Further, the mixed solvent tank 12 is provided with a valve 22 that can allow external air to flow in. The tube 112 that connects the replenishment tank 210 and the IN tank 10 is provided with a valve 212 and a pump 211 for adjusting flow of replenishment ink. Further, the replenishment tank 210 is provided with a valve 213 that can allow external air to flow in.

The inkjet system 1 is a cyclic type of system. The inkjet system 1 includes a pump 24 and a tube 111. Ink recovered to the OUT tank 11 is drawn out by the pump 24 and returned to the IN tank 10 via the tube 111. In a cyclic system, ink always flows in the inkjet head 105, preventing ink clogging and solidification.

The inkjet system 1 includes, connected to the IN tank 10 via a tube 109, a valve 17 and a pump 16 for making negative pressure in the IN tank 10, and a pressure gauge 18 that measures pressure in the IN tank 10. Similarly, the inkjet system 1 includes, connected to the OUT tank 11 via a tube 110, a valve 20 and a pump 19 for making negative pressure in the OUT tank 11, and a pressure gauge 21 that measures pressure in the OUT tank 11.

Further, the inkjet system 1 includes a control unit 13 that controls the inkjet head 105, each pump, and each valve. The control unit 13 monitors pressure in the IN tank 10 via the pressure gauge 18 and monitors pressure in the OUT tank 11 via the pressure gauge 21. The control unit 13 outputs instructions to open the valve 17 and the valve 20, and to drive the pump 16 and the pump 19. Here, the control unit 13 controls the pump 16 and the pump 19 to create an appropriate pressure difference between pressure in the IN tank 10 and pressure in the OUT tank 11. This pressure difference serves as a driving force that circulates ink in the inkjet head 105. Pressure in the inkjet head 105 is considered to be a negative pressure at a value between pressure in the IN tank 10 and pressure in the OUT tank 11. Thus, ink is prevented from leaking under its own weight from the inkjet head 105. The control unit 13 outputs instructions to drive the pump 24, causing ink to circulate.

Further, the control unit 13 outputs instructions to regularly or irregularly open the valve 15 and the valve 212, and drive the pump 14 and the pump 211. Thus, mixed solvent is added to the IN tank 10 from the mixed solvent tank 12 and replenishment ink is added to the IN tank 10 from the replenishment tank 210. Air of a flow rate adjusted by the valve 22 may be allowed to flow into the mixed solvent tank 12, or a pump (not illustrated) may be provided to gradually draw out gas in the mixed solvent tank 12. Pressure in the mixed solvent tank 12 is preferably at least slightly higher than pressure in the IN tank 10 and at least slightly higher than pressure in the OUT tank 11. Thus, mixed solvent can be allowed to flow smoothly from the mixed solvent tank 12 to the IN tank 10. Similarly, air of a flow rate adjusted by the valve 213 may be allowed to flow into the replenishment tank 210, or a pump (not illustrated) may be provided to gradually draw out gas in the replenishment tank 210. Pressure in the replenishment tank 210 is preferably at least slightly higher than pressure in the IN tank 10 and at least slightly higher than pressure in the OUT tank 11. Thus, replenishment ink can be allowed to flow smoothly from the replenishment tank 210 to the IN tank 10. The control unit 13 may control the valve 22 and the valve 213.

Further, the control unit 13 includes timekeeping units 13c, 14c, 211c that measure time passing, and a quantity of mixed solvent according to a predefined time measured by the timekeeping unit 13c is added to the IN tank 10 from the mixed solvent tank 12. Operational flow of the control unit 13 is described later. Operations of the timekeeping units 14c, 211c are also described along with the operational flow of the control unit 13.

(2) Structure of Inkjet Device 100

FIG. 2 is a perspective view showing the inkjet device 100. The inkjet device 100 includes the inkjet head 105, the IN tank 10 connected to the inkjet head 105 via the IN tube 106, and the OUT tank 11 connected to the inkjet head 105 via the OUT tube 107. The inkjet device 100 further includes a stage 101, a slider 102A provided on the stage 101, and a rail 102B onto which the slider 102B is fitted. Further, the inkjet device 100 includes a base 103 abutting the slider 102A and fixed to the slider 102A. A substrate S is mounted on the base 103. The substrate S is held on the base 103 by the action of a plurality of air suction holes (not illustrated) provided on the base 103. The inkjet device 100 further includes a gantry 104 to which the inkjet head 105 is fixed. The IN tube 106 and the OUT tube 107 are connected to the inkjet head 105 via the gantry 104. A side of the inkjet head 105 facing the substrate S has a plurality of nozzles (not illustrated). The slider 102A is slidable in an X-axis direction on the rail 102B. The base 103 on which the substrate S is fixed is pushed by the slider 102A to slide in the X-axis direction on the rail 102B. Ink is applied onto the substrate S from the nozzles of the inkjet head 105 while the base 103 on which the substrate S is fixed passes under the gantry 104. By the time the base 103 on which the substrate S is fixed has finished passing under the gantry 104, ink has been applied to desired portions of an entire surface of the substrate S.

(3) Composition Ratio and Addition Amounts of Mixed Solvent in the Mixed Solvent Tank 12

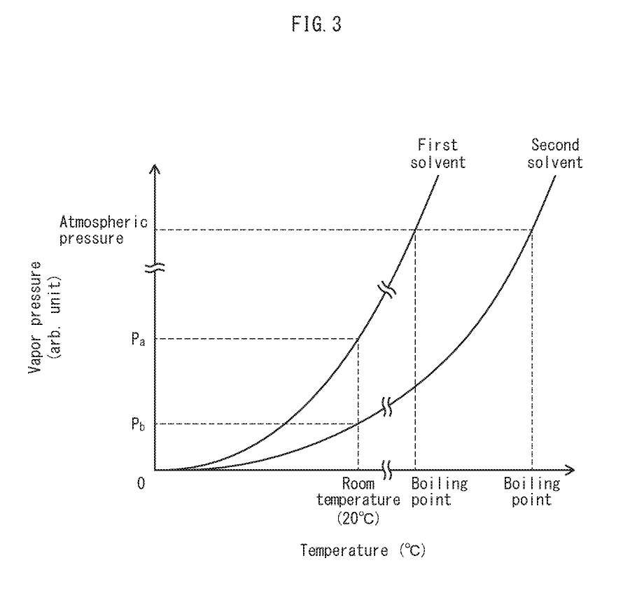

According to the embodiment, ink includes functional material, a first solvent, and a second solvent that has a higher boiling point and viscosity than the first solvent. FIG. 3 is a schematic diagram for describing a relationship between temperature, vapor pressure, and boiling point. From a surface of a liquid, a substance of the liquid volatilizes at room temperature. Vapor pressure is the pressure, at a given temperature, at which the substance's gas phase equilibrates with its liquid phase. A substance with a high vapor pressure at a temperature has a higher volatility than a substance with a low vapor pressure at the temperature. Accordingly, a vapor pressure Pₐ of the first solvent at room temperature (for example, 20° C.) may be considered as an indicator of the ease of volatilization of the first solvent at room temperature. Similarly, a vapor pressure P_{b} of the second solvent at room temperature may be considered as an indicator of the ease of volatilization of the second solvent at room temperature. Pₐ is greater than P_{b}, and therefore the first solvent volatilizes more easily than the second solvent.

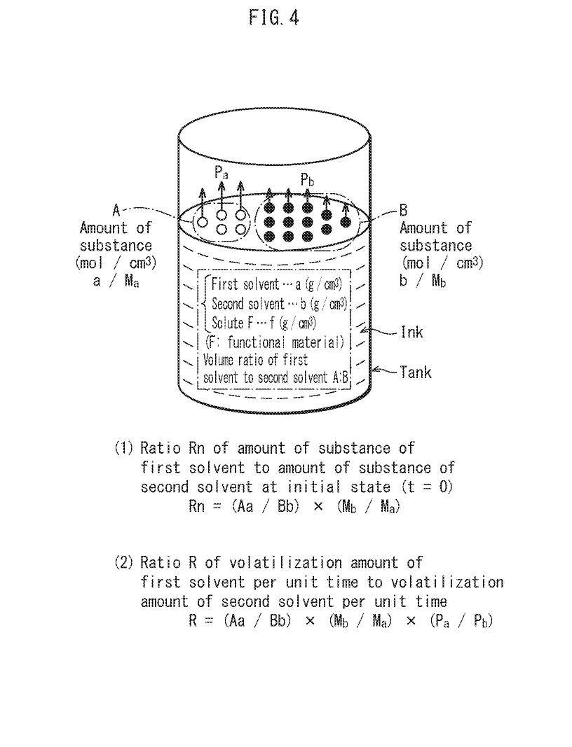

FIG. 4 is a schematic diagram for describing change over time of a ratio in ink of the first solvent to the second solvent. In the tank, a functional material F, the first solvent, and the second solvent are mixed to form ink. In the ink at room temperature, a (g/cm³) is the mass per unit volume of the first solvent, b (g/cm³) is the mass per unit volume of the second solvent, Mₐ is the molecular weight of the first solvent, and M_{b} is the molecular weight of the second solvent. Further, a ratio of volume of the first solvent to volume of the second solvent is A:B. Thus, at an initial state immediately after ink preparation (t=0), a ratio Rₙ of an amount of substance of the first solvent nₐ (mol) to an amount of substance of the second solvent n_{b} (mol) is as follows:

Rₙ=nₐ/n_{b}=(Aa/Mₐ)/(Bb/M_{b})=(Aa/Bb)×(M_{b}/Mₐ)

This ratio is assumed to be the same even in the vicinity of a surface of the ink in liquid form. Then, the first solvent and the second solvent volatilize from the liquid surface of the ink. Subsequently, time passes. As already described, the vapor pressure Pₐ of the first solvent indicates ease of volatilization of the first solvent at room temperature. Further, the vapor pressure P_{b} of the second solvent indicates ease of volatilization of the second solvent at room temperature. Thus, at room temperature, a volatilization amount Eₐ per unit time of the first solvent and a volatilization amount E_{b} per unit time of the second solvent are as follows. Here, Cₛₜ is a proportional constant determined by surface area of the liquid surface of the ink, internal pressure of the tank, etc.

Eₐ=Cₛₜ×(Aa/Mₐ)×Pₐ

E_{b}=Cₛₜ×(Bb/M_{b})×P_{b}

Accordingly, a ratio R of the volatilization amount Eₐ per unit time of the first solvent and the volatilization amount E_{b} per unit time of the second solvent is as follows.

R=Eₐ/E_{b}=(Aa/Bb)×(M_{b}/Mₐ)×(Pₐ/P_{b})

The first solvent and the second solvent volatize at the ratio R of volatilization amounts described above. Accordingly, in order to maintain the ratio Rₙ of amount of substance of the first solvent and amount of substance of the second solvent at the initial state, an amount of mixed solvent should be added which is a mix of the first solvent and the second solvent at the ratio R of volatilization.

A composition ratio of the mixed solvent to be added is determined as described above, but how to determine a volume V (cm³) of mixed solvent to be added is the next problem. As solvent in the IN tank 10 volatilizes, concentration of the functional material, which is a solute, increases, and viscosity of the ink increases. As a functional material, for example, a macromolecular material that has an average molecular weight of 10000 or more is used. In an inkjet device, as viscosity of ink increases, volume of ink droplets of the inkjet changes, and film thickness of a functional layer deviates from a designed value. Thus, a change in ink viscosity is preferably suppressed as much as possible. It is difficult to obtain correct measurements of viscosity changes on a scale of a single hour or a single day because of variation in viscosity measurements, etc. The mixed solvent may be added so that viscosity approaches a fixed value while measuring viscosity during production, but a more realistic method is to pre-define an amount of mixed solvent to add per unit time before production. According to the embodiment, as a preparatory step before actual production, a volume Q1 (cm³) per unit time of the mixed solvent to add to ink stored in the inkjet device is obtained beforehand. A method is adopted of only adding the pre-defined volume Q1 per unit time at the production stage. The following describes this method.

First, an average change rate C1 of ink viscosity is determined. The valve 15 is closed, and the inkjet system 1 is kept in operation without ejecting ink (see FIG. 1). Thus, ink is not ejected and therefore a total amount of ink in the IN tank is constant. During actual production, ink is ejected and ink is consumed, but total ink in the inkjet system 1 is far greater than ink consumption during production, and therefore the influence of ink consumption may be ignored in this case. When accuracy is desired and ink may be wasted, a substrate may be flushed and ink continuously ejected onto the substrate. Alternatively, without actually operating the inkjet system 1, results may be obtained by laboratory level experimental work.

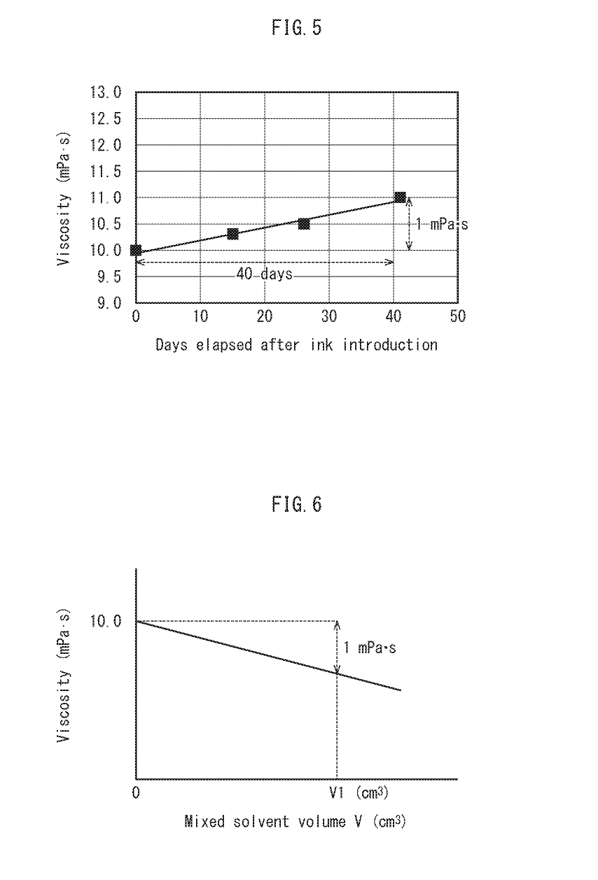

Here, ink in the IN tank 10 at initial running (t=0) of the inkjet system 1 and ink in the IN tank 10 after tens of days have elapsed from initial running are collected. Viscosity of the collected ink is measured. Viscosity is measured by using a controlled stress type of viscometer AR-G2 (TA instruments) at room temperature (20° C.). A relationship is determined between number of elapsed days (number of days elapsed after ink introduction) from initial running of the inkjet system 1 and viscosity. Results are shown in FIG. 5. From these results, according to the embodiment, it can be seen that in approximately 40 days, viscosity increased by approximately 1 mPa·s. Represented as a general formula, assuming viscosity increases by y when a time x has elapsed, an average change rate C1 of ink viscosity is as follows.

C1=y/x (i)

Next, an average change rate C2 of ink viscosity with respect to volume of mixed solvent is obtained. Here, instead of using the inkjet system 1, for simplicity, this was determined by laboratory level experimental work. Ink in an initial state was put in a beaker and covered. Then a pre-determined ratio of the mixed solvent was added. A volume V (cm³) of the added mixed solvent was measured and added to the ink in the beaker, then ink collected from the beaker, and viscosity of the ink measured. Results are shown in FIG. 6. From these results it can be seen that to decrease viscosity by approximately 1 mPa·s, in order to suppress a change in viscosity, it suffices to add V1 (cm³) of the mixed solvent. Expressed as a general formula, when V1 is a volume of added solvent and y is a decrease in viscosity, the average rate of change C2 of ink viscosity with respect to volume of the mixed ink is as follows.

C2=y/V1 (ii)

From a relationship between (i) and (ii), the volume Q1 per unit time of the mixed solvent to be added to suppress a change in ink viscosity is as follows.

Q1=V1/x=C1/C2

(4) Operational Flow of Control Unit 13

(4-1) Overall Operational Flow of Control Unit 13

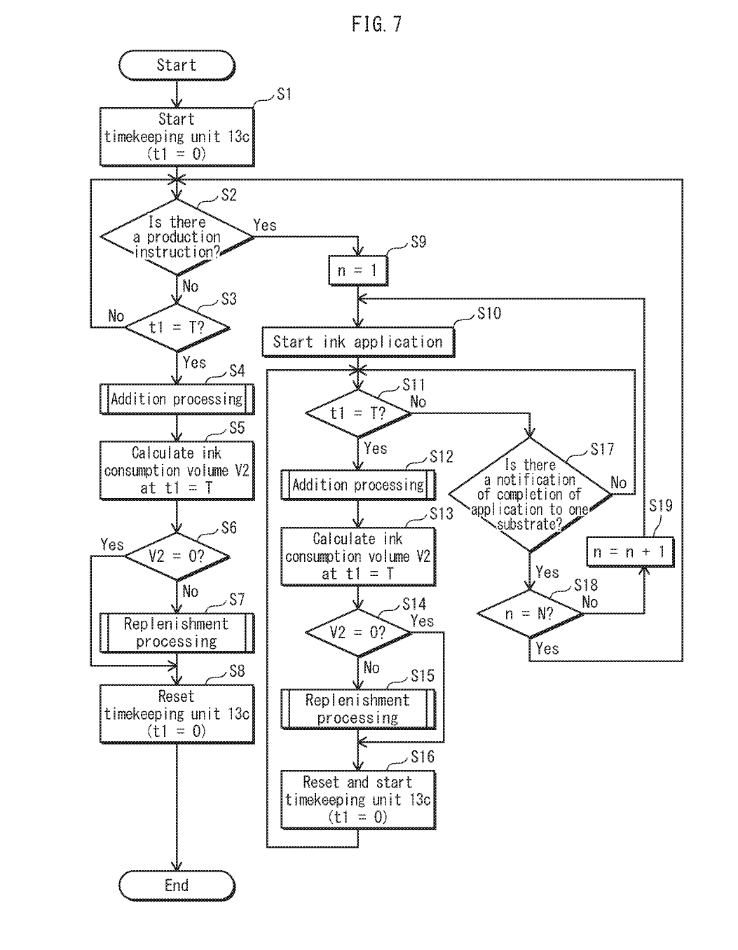

Overall operational flow of the control unit 13 when the product is in production is described below, with reference to FIG. 7.

When the control unit 13 starts, the timekeeping unit 13c of the control unit 13 starts (t1=0, step S1). When there is a production instruction (“Yes” at step S2), the control unit 13 enters production processing (step S9) and when there is no production instruction (“No” at step S2), the control unit 13 enters a standby state (step S3). A production instruction is accepted from a factory operator. When the inkjet system 1 is applied to production of an organic EL display panel, a production instruction includes, for example, information such as a model of panel to be produced and a total number N of sheets of substrate to be produced.

When there is a production instruction (“Yes” at step S2), the control unit 13 first sets a variable n to 1 (step S9). Here, n is a natural number and is a variable indicating an ordinal number of a substrate being processed. Subsequently, the control unit 13 outputs an instruction to the inkjet head 105 to start ink application (step S10). When the inkjet head 105 accepts an instruction to apply ink from the control unit 13, the inkjet head 105 applies ink onto the substrate in a predefined sequence. Subsequently, the control unit 13 determines whether or not the time t1 of the timekeeping unit 13c has reached a predefined time T (step S11). The predefined time T is a time interval at which the mixed solvent and the replenishment ink is added to the IN tank 10, and is set, for example, in hourly units such as one hour, two hours, or three hours, or day units such as one day, two days, or three days. When the time t1 of the timekeeping unit 13c has not reached the predefined time T (“No” at step S11), the control unit 13 determines whether or not there is a notification from the inkjet head 105 indicating that application onto the first substrate has finished (step S17). When there is no such notification (“No” at step S17), ink is still being applied to the first substrate, and therefore processing returns to step S11. When there is such a notification (“Yes” at step S17), the control unit 13 determines whether or not n has reached a total number N of substrates to be produced (step S18). When n has reached N (“Yes” at step S18), application of ink to N substrates that were to be produced has finished, and therefore processing returns to step S2, to wait for a subsequent production instruction. When n has not reached N (“No” at step S18), the variable n is incremented (step S19), and processing returns to step S10.

When, during production, the time t1 of the timekeeping unit 13c reaches the predefined time T (“Yes” at step S11), addition processing is performed to add the mixed solvent to the IN tank 10 (step S12). Details of the addition processing are provided under heading (4-2). When the addition processing is finished, the control unit 13 calculates an ink consumption amount V2 of ink consumed in the time taken for the time t1 to reach the predefined time T (step S13). Calculation of the ink consumption amount V2 is performed by multiplying an ejection amount per nozzle of the inkjet head 105 by the number of nozzles used per substrate, and multiplying again by the number of substrates produced in the time taken for the time t1 to reach the predefined time T. As long as V2 is not zero (“No” at step S14), a V2 amount of ink is consumed by production, and therefore a replenishment process is performed of replenishing ink in the IN tank 10 by the amount of consumed ink (step S15). Details of the replenishment processing are provided under heading (4-3). When V2 is zero (“Yes” at step S14), the number of substrates produced in the time taken for the time t1 to reach the predefined time T is zero, and therefore ink has not been consumed and the replenishment processing is skipped. Subsequently, the timekeeping unit 13c is reset and restarted (t1=0, step S16). Processing returns to step S11.

However, when there is no production instruction at step S2 (“No” at step S2), the control unit 13 determines whether or not the time t1 of the timekeeping unit 13c has reached the predefined time T (step S3). When not reached (“No” at step S3), processing returns to step S2. When reached (“Yes” at step S3), processing from step S4 to step S7 is performed. Processing from step S4 to step S7 is identical to processing from step S12 to step S15, and therefore description is omitted here. However, in step S8, the timekeeping unit 13c is only reset, and not restarted (t1=0, step S8). Subsequently, after the control unit 13 temporarily enters an end state, it is started again, and processing from step S1 is repeated.

The following describes addition processing in FIG. 7 (step S4, step S12) and replenishment processing (step S7, step S15).

(4-2) Addition Processing

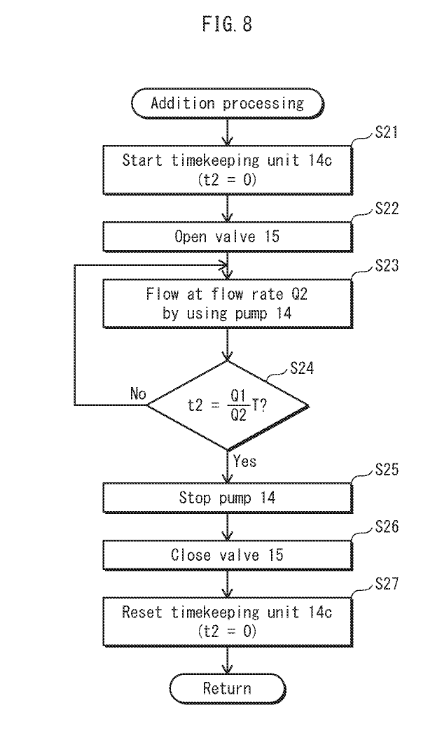

FIG. 8 shows operational flow of addition processing.

First, the timekeeping unit 14c of the control unit 13 starts (t2=0, step S21). Subsequently, the control unit 13 opens the valve 15 (step S22). The valve 15, for example, is a valve for which only opening and closing can be controlled. Subsequently, the control unit 13 causes the mixed solvent to flow to the IN tank 10 at a flow rate Q2 by using the pump 14 (step S23). Subsequently, the control unit 13 determines whether or not the time t2 of the timekeeping unit 14c has reached (Q1/Q2)T (step S24). The mixed solvent in the mixed solvent tank 12 continues to flow to the IN tank 10 until the time t2 of the timekeeping unit 14c reaches (Q1/Q2)T. The following describes a case in which the time t2 of the timekeeping unit 14c reaches (Q1/Q2)T (“Yes” at step S24). As stated above, Q1 is a volume per unit time of the mixed solvent to add to ink in order to suppress a change in viscosity of the ink in the IN tank 10. As shown in the flowchart of FIG. 7, each time the predefined time T occurs the mixed solvent is added. Volume required for one addition is a volume determined by the product of Q1 and T. When the time t2 reaches (Q1/Q2)T, assuming the mixed solvent flowed at the flow rate Q2, a volume require for one addition (Q1×T) is added. Subsequently, the control unit 13 stops the pump 14 (step S25), and the control unit 13 closes the valve 15 (step S26). Finally, the timekeeping unit 14c is reset (t2=0, step S27).

(4-3) Replenishment Processing

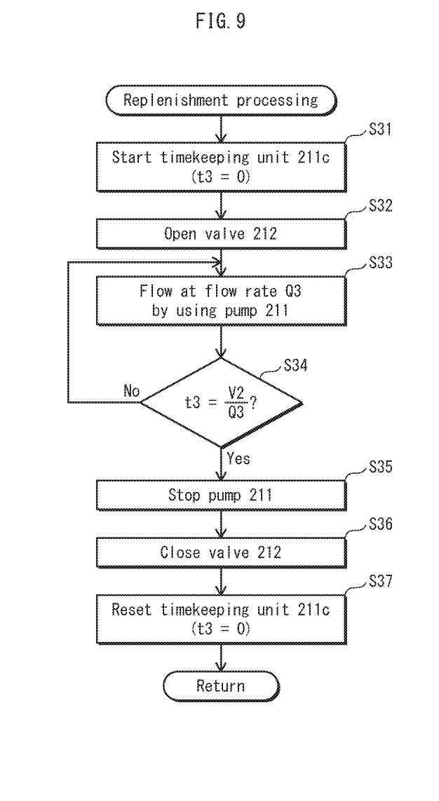

FIG. 9 shows operational flow of replenishment processing.

First, the timekeeping unit 211c of the control unit 13 starts (t3=0, step S31). Subsequently, the control unit 13 opens the valve 212 (step S32). The valve 212, for example, is a valve for which only opening and closing can be controlled. Subsequently, the control unit 13 causes the replenishment ink to flow to the IN tank 10 at a flow rate Q3 by using the pump 211 (step S33). Subsequently, the control unit 13 determines whether or not the time t3 of the timekeeping unit 211c has reached V2/Q3 (step S34). Replenishment ink in the replenishment tank 210 continues to flow to the IN tank 10 until the time t3 of the timekeeping unit 211c reaches V2/Q3. The following describes a case in which the time t3 of the timekeeping unit 211c reaches V2/Q3 (“Yes” at step S34). As stated above, the volume V2 is an amount of ink consumed in the time taken for the timekeeping unit 13c of the control unit 13 to reach the predefined time T. Accordingly, at the flow rate Q3, when the time t3 reaches V2/Q3, the volume V2 of replenishment ink equivalent to a consumed volume is added to the IN tank 10. Subsequently, the control unit 13 stops the pump 211 (step S35), and the control unit 13 closes the valve 212 (step S36). Finally, the timekeeping unit 211c is reset (t3=0, step S37).

(5) Consideration

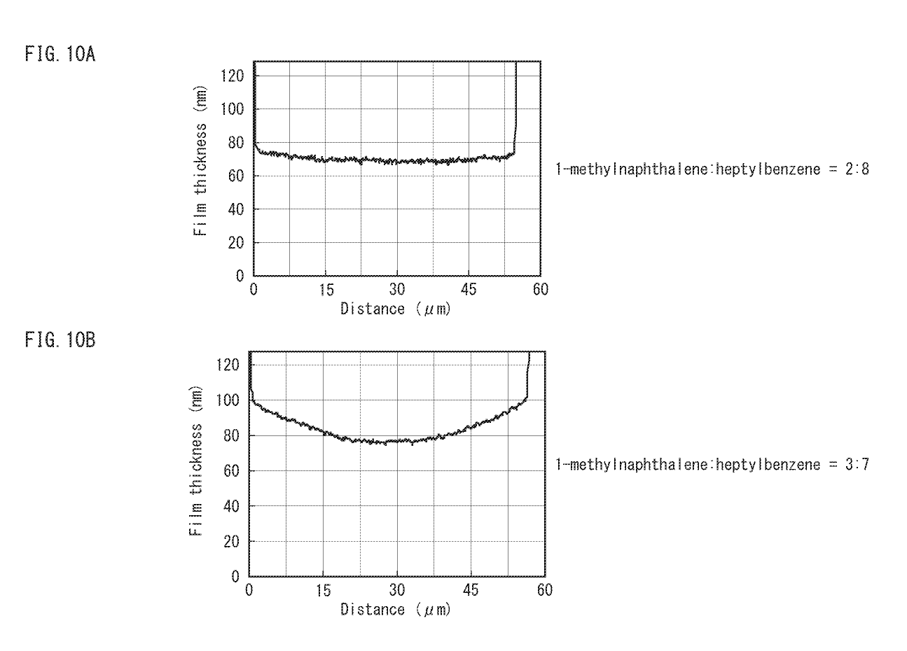

Here, the composition ratio of the mixed solvent added to the IN tank 10 from the mixed solvent tank 12 is examined. In simple terms, without considering the amount of substance of solvent and volatilization per unit time, it may be considered that it suffices to add the mixed solvent (at a mass ratio a:b of the first solvent to the second solvent) so that only viscosity becomes identical to the initial running state of the inkjet system 1. However, although viscosity is important, it is preferable to suppress change over time of a composition ratio of each solvent stored in the IN tank 10. FIG. 10A and FIG. 10B show graphs illustrating this point. Here, heptylbenzene was used as the first solvent and 1-methylnaphthalene was used as the second solvent. As a functional material to form a functional layer, an organic light-emitting material was used. A preferred example of an organic light-emitting material is a copolymer of polydioctylfluorene and polydihexylfluorene (F8-F6). Boiling points of the first solvent and the second solvent are 235° C. and 244° C., respectively. Viscosities of the first solvent and the second solvent are 13.2 mPa·s and 22.1 mPa·s, respectively. The second solvent has a higher boiling point and viscosity than the first solvent. FIG. 10A shows results of measuring surface shape of a functional layer formed by an ink using a mixed solvent in which the second solvent and the first solvent are mixed at a ratio of 2:8. FIG. 10B shows results of measuring surface shape of a functional layer formed by an ink using a mixed solvent in which the second solvent and the first solvent are mixed at a ratio of 3:7. When composition ratio of the solvents is 2:8, film thickness is substantially constant at approximately 70 nm. In contrast, when composition ratio is 3:7, film thickness becomes thicker than 70 nm, and surface shape becomes concave. Thus, a composition ratio of solvents in ink is an important factor in determining surface shape of a functional layer. According to the embodiment, the mixed solvent is prepared taking into consideration a composition ratio that corresponds to the amount of volatilization per unit time of each solvent. Furthermore, the mixed solvent is added to ink stored in the inkjet device 100. Thus, changes in composition ratio of mixed solvent in ink can be suppressed.

(6) Method for Manufacturing Organic EL Display Device

A method for manufacturing an organic EL display device 10000 is described as an example of applying the method of managing components of ink of the embodiment.

(6-1) Schematic Configuration of Organic EL Display Device 10000

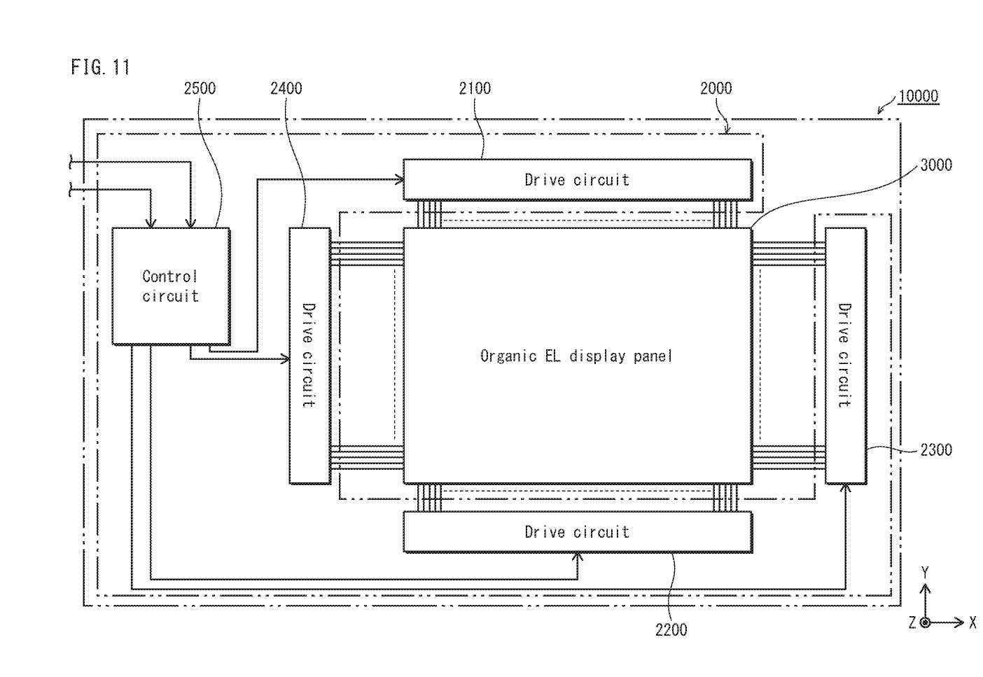

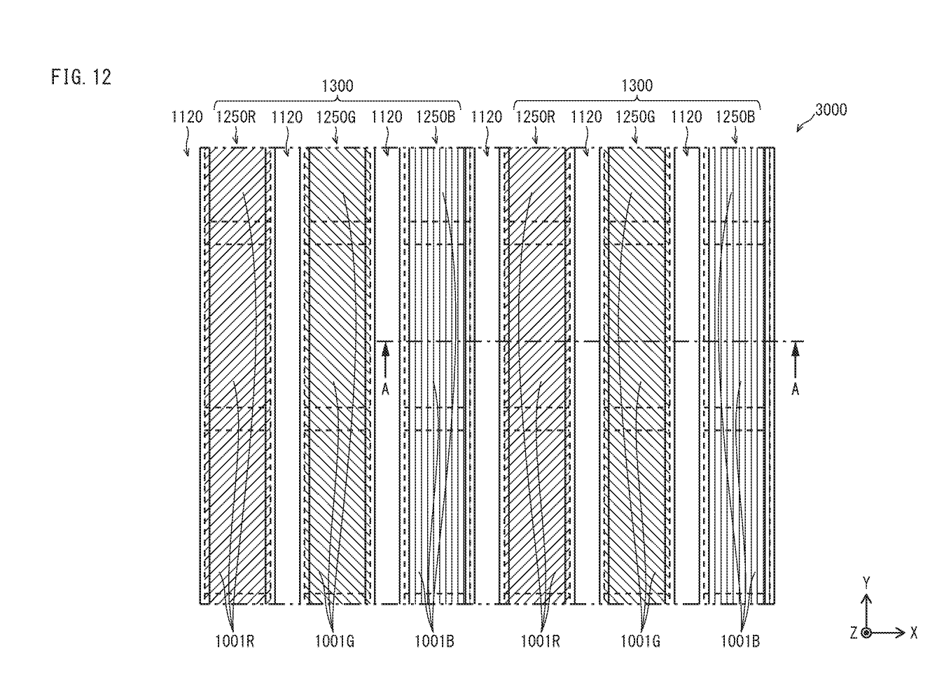

A schematic configuration of the organic EL display device 10000 is described with reference to FIG. 11 and FIG. 12. As shown in FIG. 11, the organic EL display device 10000 includes an organic EL display panel 3000 and drive/control circuitry 2000 connected thereto. FIG. 12 is a plan view of the organic EL display panel 3000. As shown in FIG. 12, in the organic EL display panel 3000 a plurality of organic EL elements 1001R, 1001G, 1001B are arranged in two dimensions in an X direction and a Y direction. According to the organic EL display panel 3000, the organic EL elements 1001R emit red (R) light, the organic EL elements 1001G emit green (G) light, and the organic EL elements 1001B emit blue (B) light. As shown in FIG. 11, the drive/control circuitry 2000 in the organic EL display device 10000 includes four drive circuits 2100, 2200, 2300, 2400 and one control circuit 2500.

(6-2) Configuration of Organic EL Display Panel 3000

As shown in FIG. 12, the organic EL display panel 3000 has groove regions 1250R, 1250G, 1250B separated by a plurality of banks 1120 that extend in the Y-direction. The groove regions 1250R, 1250G, 1250B are groove regions for red, green, and blue, respectively, and the organic EL elements 1001R, 1001G, 1001B of corresponding light-emission colors are arranged along the groove regions in the Y direction.

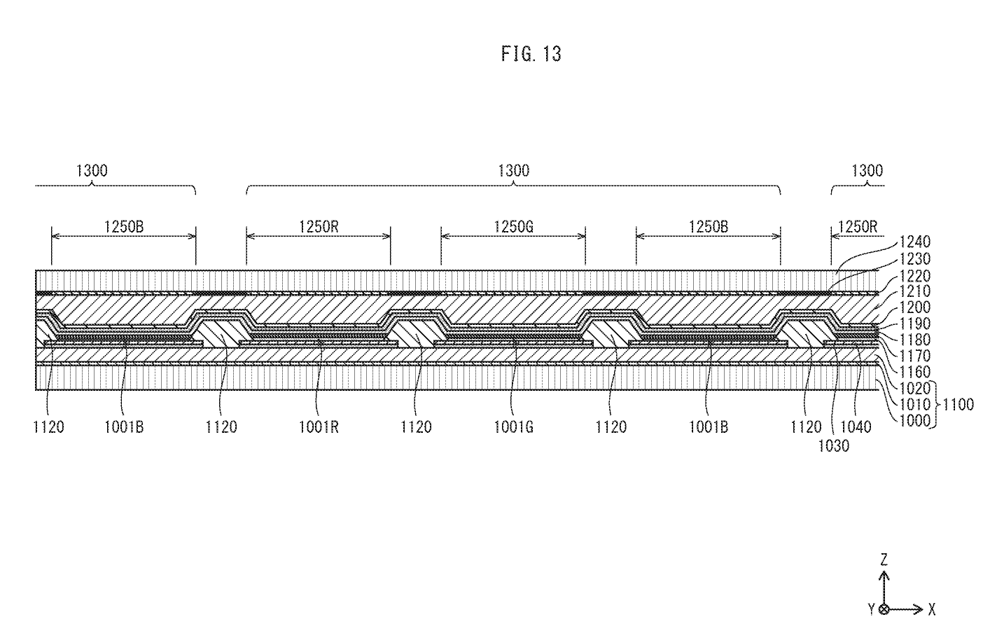

FIG. 13 shows a cross section of A-A in FIG. 12. The organic EL display panel 3000 is based on a TFT substrate that has a TFT layer 1010 formed on a substrate 1000. Although not shown in detail, the TFT layer 1010 includes gate, source, and drain electrodes, a semiconductor layer, and a passivation film. An interlayer insulating layer 1020 is layered on the TFT substrate to form an underlying substrate 1100. A top surface of the interlayer insulating layer 1020 is formed to be substantially flat, and the organic EL elements 1001R, 1001G, 1001B are formed thereon.

Each of the organic EL elements 1001R, 1001G, 1001B have essentially the same configuration, including a pixel electrode (anode) 1030, a hole injection layer 1040, a hole transport layer 1160, a light-emitting layer 1170, an electron transport layer 1180, and a cathode 1190 layered in this order on the interlayer insulating layer 1020.

The banks 1120 are formed on the interlayer insulating layer 1020, covering X-direction edges of the hole injection layer 1040. The hole transport layer 1160 and the light-emitting layer 1170 are formed between the banks 1120. The hole transport layer 1160 and the light-emitting layer 1170 are formed to be continuous in the Y direction.

On the light-emitting layer 1170 and entirely covering exposed side surfaces and top surfaces of the banks 1120, the electron transport layer 1180, the cathode 1190, and a sealing layer 1200 are layered in this order. A substrate 1240 that has a color filter layer 1220 and a black matrix layer 1230 is attached to the sealing layer 1200 with a resin layer 1210 disposed therebetween.

(6-3) Organic EL Display Panel 3000 Manufacturing Method

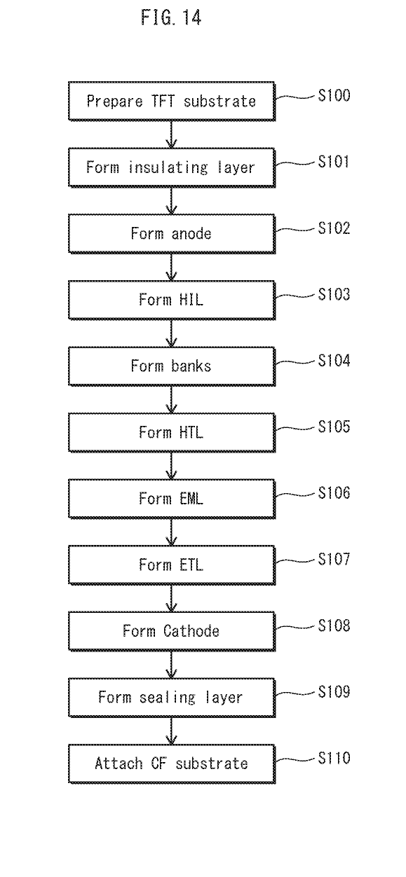

A method of manufacturing the organic EL display panel 3000 is described below, with reference to the process diagram of FIG. 14. Manufacture of the organic EL display panel 3000 starts with preparing the TFT substrate (step S100). The TFT substrate is formed by forming the TFT layer 1010 on the top surface of the substrate 1000, and is manufactured by a publicly-known technique. Subsequently, an organic material is applied on the TFT substrate to form the interlayer insulating layer 1020 (step S101).

Thus, on the interlayer insulating layer 1020 of the underlying substrate 1100, the pixel electrode (anode) 1030 and the hole injection layer (HIL) 1040 are layered in this order (steps S102, S103). The pixel electrode 1030 is formed, for example, by forming a metal film by using sputtering or vacuum deposition, and then patterning by photolithography and etching.

The hole injection layer 1040 is formed, for example, by forming a film from a metal oxide (for example, tungsten oxide) by using sputtering, and then patterning by photolithography and etching.

Subsequently, a bank-attached substrate is produced by forming the banks 1120 (step S104). The banks 1120 are initially a bank material (negative type photosensitive resin compound) applied uniformly on the substrate to form a bank material layer. A photomask that has openings matching a pattern of the banks 1120 is overlaid on the bank material layer and the photomask is exposed to light from above. Subsequently, the bank material is patterned by washing away excess bank material by using an alkaline developer to form the banks 1120.

Subsequently, the hole transport layer (HTL) 1160 is formed in each of the groove regions 1250 defined by the banks 1120 (step S105). In forming the hole transport layer 1160, ink containing a constituent material of the hole transport layer 1160 is applied to a groove region between adjacent ones of the banks 1120 by using a wet method, then dried. The hole transport layer 1160 is formed by using the inkjet system 1 of the embodiment described above.

Similarly, the light-emitting layer (EML) 1170 is formed in each of the groove regions 1250 defined by the banks 1120 (step S106). The light-emitting layer 1170 is also formed by applying, then drying, an ink containing constituent material. The light-emitting layer 1170 is also formed by using the inkjet system 1 of the embodiment described above.

Subsequently, the electron transport layer (ETL) 1180, the cathode 1190, and the sealing layer 1200 are layered in this order, covering the light-emitting layer 1170 and exposed side surfaces and top surfaces of the banks 1120 (steps S107, S108, S109). The electron transport layer 1180, the cathode 1190, and the sealing layer 1200 can be formed by sputtering, for example.

Subsequently, the color filter (CF) substrate, which includes the color filter layer 1220 and the black matrix layer 1230 formed on the substrate 1240, is attached to complete the organic EL display panel 3000 (step S110).

Note that although the hole injection layer (HIL) 1040 is formed on the pixel electrode (anode) 1030 according to the above description, the hole injection layer (HIL) 1040 is not necessarily formed. The hole transport layer (HTL) 1160 and the light-emitting layer (EML) 1170 may be formed directly onto the pixel electrode (anode) 1030 by using the inkjet system 1 described according to the embodiment.

Further, although the electron transport layer (ETL) 1180 and the cathode 1190 are formed on the light-emitting layer 1170 according to the above description, the electron transport layer (ETL) 1180 is not necessarily formed. The cathode 1190 may be formed directly onto the light-emitting layer 1170.

That is, a functional layer formed by using the inkjet system 1 of the embodiment may be formed above the pixel electrode (anode) 1030, and the cathode 1190 may be formed above the functional layer. Here, “above” an electrode or layer may be interpreted to mean on the electrode or the layer (in direct contact with the electrode or the layer), or to mean above the electrode or the layer (not in direct contact with the electrode or the layer).

(6-4) Organic EL Display Device 10000 Manufacturing Method

The drive circuits 2100, 2200, 2300, 2400 are mounted on the organic EL display panel 3000 complete as described above. The control circuit 2500 is connected to the drive circuits 2100, 2200, 2300, 2400, completing the organic EL display device 10000 (see FIG. 11).

The organic EL display device 10000 manufactured as described above is formed having a desired value for film thickness of a functional layer (according to the embodiment, the hole transport layer and the light-emitting layer), and a high flatness of the functional layer. Accordingly, variation in light-emitting properties within a display panel and between each display panel is suppressed. Thus, according to the method of manufacturing the embodiment, high-quality organic EL display panels and organic EL display devices can be manufactured, for which production variation is suppressed.

### Other Items

(1) According to the embodiment, the mixed solvent and the replenishment ink are added at intervals of the predefined time T, but the present invention is not limited to this example. The mixed solvent and/or the replenishment ink may be added continuously, instead of at intervals of the predefined time T.

(2) According to the embodiment, addition of the mixed solvent and addition of the replenishment ink is performed at the predefined time T, but the present invention is not limited to this example. Addition of the mixed solvent and addition of the replenishment ink may be performed independently at different predefined time intervals.

(3) According to the embodiment, a viscometer is not attached to the inkjet system 1, but a simple viscometer may be provided in the system, and may monitor viscosity change to determine the additional amount of the mixed solvent.

(4) According to the embodiment, a macromolecular material is used as an example of a functional material, but a low molecular weight material (average molecular weight under 10000) may be used.

(5) According to the embodiment, the valves are only opened and closed, and the pumps cause flow of solvent and ink at pre-set flow rates, but the present invention is not limited in this way. In addition to a valve being opened and closed, flow rate may be adjusted.

(6) According to the embodiment, the inkjet system 1 is mainly described on the assumption of automatic control using the control unit 13, but the present invention is not limited to this. As a method of managing components of ink, a user may manually add the mixed solvent.

(7) According to the embodiment, the mixed solvent is a mix of two types of solvent, but the present invention is not limited to this example. Three or more types of solvent may be mixed. For example, in the case of a first solvent, a second solvent, and a third solvent being used, a composition ratio of the mixed solvent may be as follows. Here, the boiling point and viscosity increase in the order of the first solvent, the second solvent, and the third solvent. At room temperature, the first solvent, the second solvent, and the third solvent have a mass per unit volume of a (g/cm³), b (g/cm³), and c (g/cm³), respectively. Molecular weights of the first solvent, the second solvent, and the third solvent are Mₐ, M_{b}, and M_{c}, respectively. At room temperature, vapor pressures of the first solvent, the second solvent, and the third solvent are Pₐ, P_{b}, and P_{c}, respectively. Further, a composition ratio of volume of the first solvent to volume of the second solvent to volume of the third solvent is A:B:C. Mixed solvent added to the IN tank 10 from the mixed solvent tank 12 could be added in the volume ratio provided below. Four or more types of solvent could be handled similarly.

(Aa/Mₐ)×Pₐ:(Bb/M_{b})×P_{b}:(Cc/M_{c})×P_{c}

(8) According to the embodiment, a simple method is adopted of adding the mixed solvent in a ratio of volatilization amounts per unit time, but the mixed solvent may be prepared by using a more accurate method of estimation. For example, gas chromatography mass spectrometry (GC/MS) may be performed on the mixed solvent in the IN tank 10 to determine which solvent has actually decreased and by how much, thereby determining the composition ratio of the mixed solvent.

(9) According to the embodiment, room temperature means from 15° C. to 40° C.

(10) According to the embodiment, a system adds the mixed solvent to the IN tank 10, but the present invention is not limited to this example. The mixed solvent may be added to the OUT tank 11, and may be added to a tube in which ink is circulating. In a case of addition to a tube, addition to the IN tube 106 that supplies ink to the inkjet head 105 is preferable.

(11) The predefined time T at which the mixed solvent is added to the IN tank 10 is preferably such that properties of the functional layer fall within specifications. As long as properties of the functional layer fall within specifications, a relatively long value may be used for the predefined time T, such as one week or one month.

(12) Discarding ink and replacing it with ink of an appropriate viscosity and composition ratio after a certain time, without using an ink circulation system such as the embodiment, may also be considered. However, the functional material is very expensive, so frequent discarding of ink is not a very realistic option.

(13) The ink component management method, inkjet system using same, and method for manufacturing the organic EL display device using the inkjet system pertaining to the present invention may be configured from an appropriate combination of partial configurations of the embodiment. Further, materials, numerical values, and the like described according to the embodiment are merely examples, and the present invention is not limited thereto. Further, it is possible to appropriately change configuration without departing from the scope of the technical idea of the present invention. The present invention is widely applicable to ink component management methods, inkjet systems using same, and methods for manufacturing organic EL display device using inkjet systems.

### INDUSTRIAL APPLICABILITY

The ink component management method, the inkjet system using same, and the method for manufacturing an organic EL display device using the inkjet system, all of which are aspects of the present invention, are widely applicable to manufacturing processes for primarily organic display devices and organic light-emitting devices.

### REFERENCE SIGNS LIST

1. Inkjet system

10. IN tank

11. OUT tank

12. Mixed solvent tank

13. Control unit

13c, 14c, 211c. Timekeeping units

15, 212. Valves

100. Inkjet device

105. Inkjet head

108. Tube

1030. First electrode (anode)

1100. Underlying substrate

1160. Functional layer (hole transport layer)

1170. Functional layer (light-emitting layer)

1190. Second electrode (cathode)

3000. Organic EL display panel

10000. Organic EL display device

1. A method for managing components of ink stored in an inkjet device under a negative pressure environment, the ink including a functional material, a first solvent, and a second solvent that has a higher boiling point and viscosity than the first solvent, the inkjet device discharging the ink via nozzles, the method comprising:
preparing a mixed solvent including a solvent identical to the first solvent and a solvent identical to the second solvent at a composition ratio that depends on a volatilization amount of the first solvent per unit time and a volatilization amount of the second solvent per unit time; and
adding the mixed solvent to the ink stored in the inkjet device.

2. The method of claim 1, wherein
R=(Aa/Bb)×(M_{b}/Mₐ)×(Pₐ/P_{b})
where R is a ratio of a volatilization amount of the solvent identical to the first solvent per unit time to a volatilization amount of the solvent identical to the second solvent per unit time, a is a mass at room temperature per unit volume of the solvent identical to the first solvent, Mₐ is a molecular weight of the solvent identical to the first solvent, Pₐ is a vapor pressure at room temperature of the solvent identical to the first solvent, b is a mass at room temperature per unit volume of the solvent identical to the second solvent, M_{b} is a molecular weight of the solvent identical to the second solvent, P_{b} is a vapor pressure at room temperature of the solvent identical to the second solvent, and A:B is a ratio of volume of the first solvent to volume of the second solvent.

3. The method of claim 1, wherein
the mixed solvent is added to the ink at a quantity Q1 per unit time, and
Q1=C1/C2
where C1 is an average rate of change of viscosity of the ink when stored in the inkjet device and the mixed solvent is not added and C2 is an average rate of change of viscosity of the ink per added amount of the mixed solvent when the mixed solvent is added to the ink.

4. The method of claim 1, wherein
the inkjet device comprises an inkjet head that includes the nozzles and an IN tank that is connected to the inkjet head and stores the ink for supplying the inkjet head, and
the adding the mixed solvent to the ink stored in the inkjet device is performed by adding the mixed solvent to the IN tank.

5. The method of claim 1, wherein
the mixed solvent is stored under a higher pressure environment than the ink stored in the ink jet device.

6. The method of claim 1, wherein
the functional material is a macromolecular organic material.

7. An inkjet system comprising:
an inkjet device that stores ink under a negative pressure environment, the ink including a functional material, a first solvent, and a second solvent that has a higher boiling point and viscosity than the first solvent, the inkjet device discharging the ink via nozzles;
a mixed solvent tank that is connected to the inkjet device via a pipe, the mixed solvent tank storing a mixed solvent including a solvent identical to the first solvent and a solvent identical to the second solvent at a composition ratio that depends on a volatilization amount of the first solvent per unit time and a volatilization amount of the second solvent per unit time;
a valve provided to the pipe; and
a control unit that controls the valve to allow the mixed solvent stored in the mixed solvent tank to be added to the inkjet device.

8. The inkjet system of claim 7, wherein
R=(Aa/Bb)×(M_{b}/Mₐ)×(Pₐ/P_{b})
where R is a ratio of a volatilization amount of the solvent identical to the first solvent per unit time to a volatilization amount of the solvent identical to the second solvent per unit time, a is a mass at room temperature per unit volume of the solvent identical to the first solvent, Mₐ is a molecular weight of the solvent identical to the first solvent, Pₐ is a vapor pressure at room temperature of the solvent identical to the first solvent, b is a mass at room temperature per unit volume of the solvent identical to the second solvent, M_{b} is a molecular weight of the solvent identical to the second solvent, P_{b} is a vapor pressure at room temperature of the solvent identical to the second solvent, and A:B is a ratio of volume of the first solvent to volume of the second solvent.

9. The inkjet system of claim 7, wherein
the mixed solvent is added to the ink at a quantity Q1 per unit time, and
Q1=C1/C2
where C1 is an average rate of change of viscosity of the ink when stored in the inkjet device and the mixed solvent is not added and C2 is an average rate of change of viscosity of the ink per added amount of the mixed solvent when the mixed solvent is added to the ink.

10. The inkjet system of claim 7, wherein
the inkjet device comprises an inkjet head that includes the nozzles and an IN tank that is connected to the inkjet head and stores the ink for supplying the inkjet head, and
the mixed solvent is added to the ink stored in the inkjet device is by adding the mixed solvent to the IN tank.

11. The inkjet system of claim 7, wherein
the mixed solvent is stored under a higher pressure environment than the ink stored in the ink jet device.

12. The inkjet system of claim 7, wherein
the functional material is a macromolecular organic material.

13. A method for manufacturing an organic EL display device, the method comprising:
preparing a lower substrate;
forming a first electrode on the lower substrate;
forming a functional layer above the first electrode, from the functional material, by using the inkjet system of claim 7; and
forming a second electrode above the functional layer.
